(19) United States
(12) Patent Application Publication
(10) Pub. No.: US 2012/0075901 A1
(43) Pub. Date: Mar. 29, 2012

(54) GEOTHERMALLY COOLED POWER CONVERSION SYSTEM

(75) Inventors: Abdolmehdi Kaveh Ahangar, Cedarburg, WI (US); Scott D. Day, Richfield, WI (US)

(73) Assignee: Rockwell Automation Technologies, Inc., Mayfield Heights, OH (US)

(21) Appl. No.: 12/893,773

(22) Filed: Sep. 29, 2010

(51) Int. Cl. H05K 7/20; H02M 1/00

(52) U.S. Cl. 363/141

(57) ABSTRACT

Embodiments of the present invention provide novel techniques for cooling power conversion circuitry. In particular, a geothermal conditioning system may be used that includes a ground loop heat exchanger. The ground loop heat exchanger may pump heat from the power conversion circuitry into the ground in order to cool the power conversion circuitry. The ground loop heat exchanger may also extract heat from the ground and direct the heat into the power conversion circuitry in order to heat the power conversion circuitry. The geothermal conditioning system may also include a surface loop heat exchanger and combine the cooling and heating abilities of both the ground loop and surface loop heat exchangers in order to improve energy efficiency.

### BACKGROUND

The present invention relates generally to the field of power conversion systems. More particularly, the present invention relates to power conversion systems that are thermally conditioned by geothermal heat exchangers.

Power conversion systems, such as solar drives, are typically used to convert an incoming direct current (DC) into an alternating current (AC). In solar applications, the emissions of solar radiation may be captured, for example, by using photovoltaic cells, and converted into DC power. The power conversion system may then convert the DC power into AC power suitable for distribution, for example, into an electric grid. Unfortunately, power conversion systems may generate excessive heat.

### BRIEF DESCRIPTION

Embodiments of the present disclosure provide novel techniques for cooling and/or heating (i.e., thermal conditioning) of power conversion systems. Power conversion systems may house thermally sensitive electronics that are rated for use in certain temperature ranges (e.g., 0° C. to 50° C.). Accordingly, thermal energy may be transferred to and from such electronics devices by the use of fluids (e.g., air, water, glycol, alcohol, etc.) powered by electrical devices such as fans and/or pumps. The fluid flow may transfer the thermal energy through heat exchangers so as to maintain the power conversion systems at a suitable temperature range. The cooling and heating embodiments described herein incorporate geothermal heat exchangers that may use less energy, produce less carbon emissions, and may provide thermal conditioning of power conversion equipment in a variety of climate zones, including tropical zones, deserts, and cold climate zones. In particular, certain embodiments of the thermal conditioning techniques described herein may combine geothermal heat exchangers with the use of traditional electrical fans and/or pumps. Indeed, in certain embodiments, the geothermal techniques described herein are capable of combining with other thermal conditioning techniques (e.g., electrical fans and pumps) in order to achieve improved energy efficiencies. In other embodiments, the geothermal techniques described herein are capable of replacing the use of, for example, electrical fans and pumps, resulting in even higher energy efficiencies.

In accordance with certain aspects, a thermally conditioned power conversion system is provided. The thermally conditioned power conversion system includes power conversion circuitry, a ground loop heat exchanger, and a controller. The controller controls cooling and/or heating of the power conversion circuitry by using a pump configured to move a heat exchanging fluid via a refrigeration fluid circulated through the ground loop heat exchanger.

In accordance with further aspects, a thermally conditioned power conversion system includes power conversion circuitry, a pump, and a ground loop heat exchanger. The power conversion circuitry is configured to receive power from a power system and to convert the power received from the power system in an alternating current (AC) power or a direct current (DC) power. The pump is configured to pump a refrigeration fluid. The ground loop heat exchanger is configured to cool or heat the power conversion circuitry by circulation of the refrigeration fluid pumped by the pump.

In accordance with still further aspects, non-transitory computer-readable medium comprising code is provided. The code is adapted to receive a value representative of a temperature of power conversion circuitry, and to calculate a difference between the received value representative of the temperature of power conversion circuitry and a desired temperature. The code is also adapted to output a command signal to pump a refrigeration fluid through a ground loop heat exchanger based upon the calculated difference to cool or heat the power conversion circuitry.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic diagram of an exemplary embodiment of a solar power generation system, according to the certain aspects of the present disclosure;

FIG. 2 is a schematic diagram of an exemplary embodiment of geothermally conditioned power conversion circuitry, according to the certain aspects of the present disclosure;

FIG. 3 is a schematic diagram of another exemplary embodiment of geothermally conditioned power conversion circuitry, according to the certain aspects of the present disclosure; and

FIG. 4 is flow chart of an exemplary embodiment of a cooling or heating logic, according to the certain aspects of the present disclosure.

### DETAILED DESCRIPTION

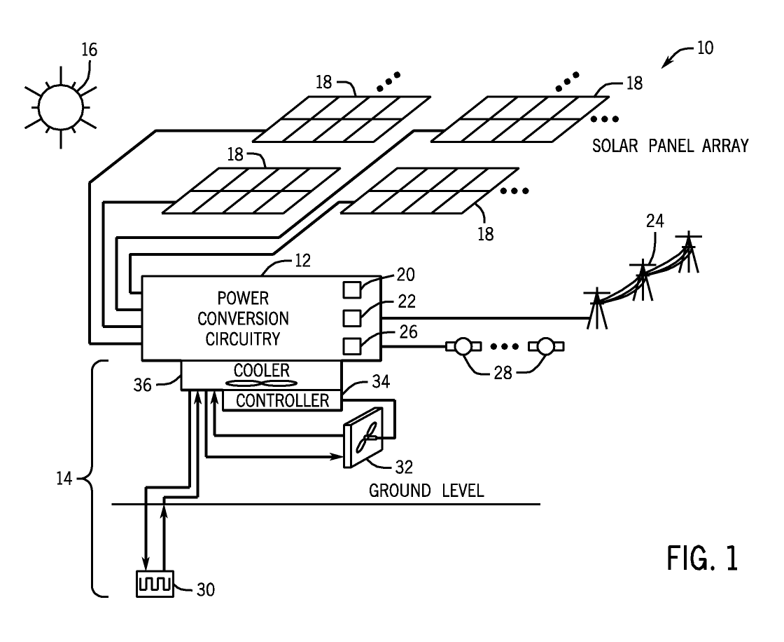

It may be beneficial to first discuss embodiments of certain power generation systems that may incorporate the techniques described herein. With this in mind, FIG. 1 is a schematic diagram of an embodiment of a solar power generation system 10 including power conversion circuitry 12 and a geothermal conditioning system 14. A power source, such as the sun 16, generates an electromagnetic radiation (e.g., sunlight), some of which may impinge upon a plurality of solar panels 18. The solar panels 18 may use, for example, a photovoltaic effect to convert the impinging solar radiation into a direct current (DC) flow of electrons. It is to be understood that while the depicted embodiment shows four solar panels 18, more or fewer solar panels 18 may be used.

The solar panels 18 may direct the resulting DC power into power conversion circuitry 12. In certain embodiments, the power conversion circuitry 12 may include, for example, power inverters 20, rectifiers 22, and other electronic circuitry suitable for converting the DC power into an alternating current (AC) power. The AC power may then be supplied, for example, to an electric grid 24 for use in providing power to residential and commercial buildings and other loads. The power conversion circuitry 12 may also include a motor drive 26, such as open DC bus drive, that may condition and reconvert the incoming DC power into AC power or DC power suitable for use in driving a variety of devices such as electric motors 28, heating ventilation and air conditioning (HVAC) units, and so forth. One example of a motor drive 26 capable of interfacing with solar panel 18 circuitry is the Allen-Bradley PowerFlex® drive, available from Rockwell Automation of Milwaukee, Wis. Indeed, the power conversion circuitry 12 may enable a more efficient utilization of the photovoltaically-generated DC power by rectifying, conditioning, and converting the DC power. It should also be understood that the power conversion circuitry 12 may be used with other power generation techniques, such as wind turbines, solar concentrators (e.g., heliostats, Stirling solar engines, parabolic troughs), and so forth.

The power conversion circuitry 12 may be rated or certified to operate at certain temperature ranges, such as approximately between 0° C. to 50° C., or −10° C. to 60° C., and so forth. However, the power conversion circuitry 12 may be located in areas that have high solar insolation. Such solar insolation is a measure of the amount of solar radiation that a certain surface area may receive over time, and may be measured in kilowatt-hours per square meter per day (KWh/m²/day). That is, the power conversion circuitry 12 may be located in geographic areas that receive a high amount of solar radiation over a time. Areas of high solar insolation may correspond to areas having above average hot weather. Accordingly, cooling of the power conversion circuitry 12 may be desired in order to achieve more optimal operating temperatures.

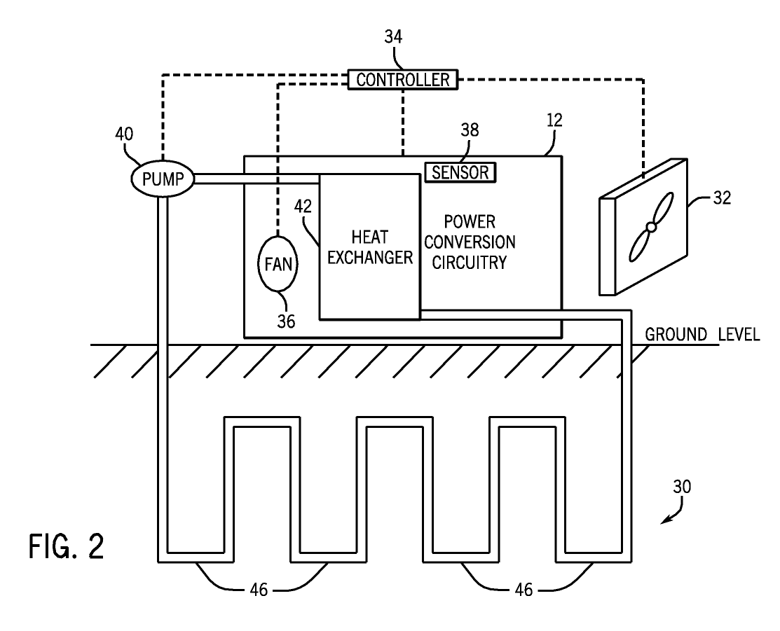

In certain embodiments, the geothermal conditioning system 14 is used to cool or heat the power conversion circuitry 12 by using a ground loop heat exchanger 30, a surface loop heat exchanger 32, a controller 34, and a cooling fan 36. The ground loop heat exchanger 30 may take advantage of thermal differentials between subsurface temperatures and ambient air temperatures in order to cool or heat a fluid (i.e., refrigeration fluid). Although the term “refrigeration fluid” is used in the present discussion, it should be understood that this refers more generally to a heat exchange fluid that acts to either heat or cool the circuitry depending upon the particular needs at the time. More specifically, the ground loop heat exchanger 30 uses subsurface or underground temperatures to heat and/or cool the fluid because subsurface temperatures maintain a nearly constant temperature range, such as between 10° C. to 20° C. Such geothermal conditioning uses the nearly constant temperatures to conserve energy because the ground itself provides the cooling or heating energy. Accordingly, the controller 34 may control cooling (or heating) operations, for example, by directing a fluid into the ground loop heat exchanger 30 in order to exchange thermal energy with the ground, as described in more detail below with respect to FIG. 2. Additionally, the controller 34 may combine the ground loop heat exchanger 30 with the surface loop heat exchanger 32 in order to increase energy efficiency. The use of the surface loop heat exchanger 32 may enable a further cooling (or heating) by including a second heat exchanger capable of removing (or adding) thermal energy from the power conversion circuitry 12. Additionally, the fan 36 may further aid the cooling (or heating) of the power conversion circuitry 12 through convection of the cool (or hot) air. That is, the fan 36 may blow the cool (or hot) air through the power conversion circuitry 12, aiding in the thermal conditioning of the power conversion circuitry 12.

FIG. 2 depicts an exemplary gas-cooled embodiment of the power conversion circuitry 12 incorporating the use of the ground loop heat exchanger 30. In the depicted embodiment, multiple pipes 46 may be buried under the ground so as to form the ground loop heat exchanger 30 suitable for conducting a thermal fluid such as air. In other embodiments, the pipes 46 may be disposed in a body of water, such as a pond, a lake, or an ocean. The pipes 46 may be manufactured out of plastic, concrete, ceramic, and/or metals (e.g., copper, iron, steel) and buried at a certain depth z. The depth of the pipes 46 may determine the temperature differences between the ground temperature and ambient temperature because ground temperatures are a function of depth. One equation that may be used to determine temperature T_{z} at a given depth z is as follows:

$${T}_{z} = {T}_{m} - {A}_{s} exp ( - {z ( \frac{π a}{365} )}^{0.5} ) cos ( \frac{2 π}{365} ( t - {t}_{0} - \frac{z}{2} {( \frac{365 a}{π} )}^{0.5} ) )$$

where Tₘ is the average annual temperature of the surface soil, Aₛ is the amplitude of the surface temperature variation, α is the thermal diffusivity of the ground, t is the time elapsed from the beginning of the calendar year (i.e. days), and t₀ is the phase constant of hours since the beginning of the year of the lowest average ground difference temperature. Accordingly, a desired ground temperature T_{z} may be found at a given depth z and used to create a thermal difference with the ambient temperature. As depicted, the ground loop heat exchanger 30 is a vertical loop. However, other embodiments may include a horizontal loop or a combination of horizontal and vertical loops. Indeed, the loops may be placed in any orientation, including angled orientations.

In order to improve thermal contact between the pipes 46 and the ground, the pipes 46 may be surrounded by sand or another material capable of enhancing conductive and/or convective heat transfer between the pipes (and the fluid circulating in them) and the ground. For example, 5 cm of sand may be placed around the pipes to increase the heat exchange between the pipes 46 and the ground. A total length L of all of the pipes may be of approximately 20 meters but may be longer or shorter based on how much capacity the ground loop heat exchanger 30 may be desired. For example, systems that may desire an increased heat exchange capability may thus include a longer L, and systems that may desire less heat exchange capability may include a shorter L. While increasing the length L may increase the amount of area suitable for heat exchange, increasing the length L may also increase the overall cost of the system as well as the amount of energy used to move a thermal exchange fluid through the pipes 46. Likewise, decreasing the length L may decrease the amount of area suitable for heat exchange and but may also decrease of the overall cost of the system and the amount of energy used to move the thermal exchange fluid. Accordingly, the length L may be set so as to define a suitable area for thermal exchange while minimizing movement of thermal fluids and system cost.

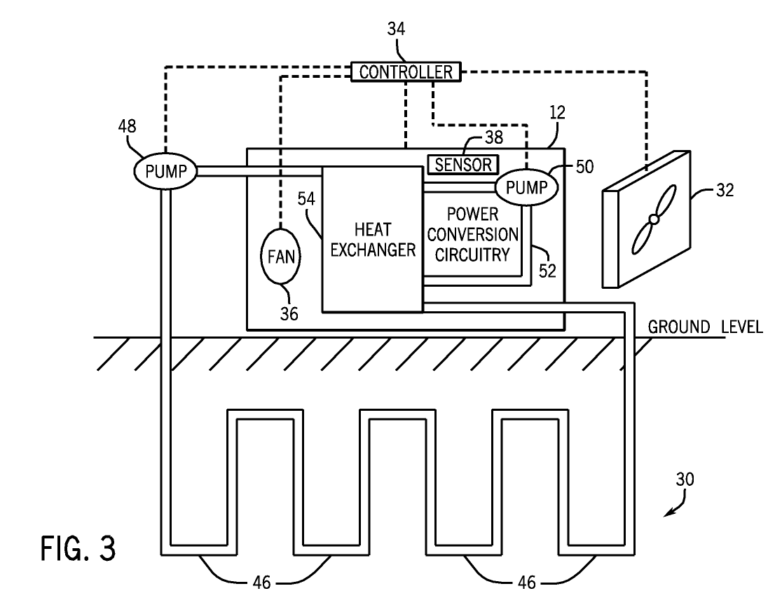

A diameter d for the pipes 46 may be chosen that allows for a suitable flow velocity of the thermal fluid (e.g., air) through the pipes so as to optimize the transfer of thermal energy between the refrigeration fluid and the ground. In certain embodiments, a diameter d may be of approximately between 0.01 to 0.5 meters, allowing for an air velocity through the pipes of approximately 1 to 10 meters/second. Larger or smaller diameters may be used, resulting in lower and higher air velocities, respectively. A preferred separation between pipes 46 is of approximately 1 to 4 meters, thus allowing for sufficient heat dissipation between the pipes 46. It is to be understood that the preceding discussion on the use of equation T_{z}, length L, diameter d, and below-ground (or underwater) placement, applies to other embodiments of the ground loop heat exchanger 30, such as the liquid-cooled embodiment described in more detail with respect to FIG. 3 below.

As the power conversion circuitry 12 generates heat, the generated heat may reach an upper bound of the rated temperature range for the power conversion circuitry 12. For example, during a summer season, an ambient summer temperature may already be near the rated temperature range, so additional heat generated by the power conversion circuitry 12 may reach the upper bounds of the rated temperature range. A sensor 38 suitable for sensing a temperature of the power conversion circuitry 12, such as a thermocouple, a non-contact optical temperature sensor, and/or a resistance temperature detector (RTD), may measure and transmit the temperature to the controller 34. Accordingly, the controller 34 may direct a pump 40 to move the refrigeration fluid (e.g., air) through the ground loop heat exchanger 30 so as to cool the power conversion circuitry 12, as described in more detail below. The controller 34 may also direct the cooling fan 36 to blow air through a heat exchanger 42 and into the power conversion circuitry 12 for added cooling.

The heat generated by the power conversion circuitry 12 may be extracted by the heat exchanger 42. More specifically, the heat exchanger 42 may be located inside a cabinet that houses the power conversion circuitry 12 and may extract heat by using, for example, folded fin devices, flat plates, and/or tube and shell devices suitable for absorbing (or releasing) heat. The heat exchanger 42 may also be an air-to-air heat exchanger, an air-to-liquid heat exchanger, or a liquid-to-liquid heat exchanger depending on the refrigeration fluids used in the heat exchanger 42 and the ground loop heat exchanger 30. That is, if the ground loop heat exchanger 30 is configured to use air as the refrigeration fluid, then the heat exchanger 42 may be an air-to-air heat exchanger or an air-to-liquid heat exchanger depending on whether the heat exchanger 42 is configure to use air or liquid as its refrigeration fluid. Likewise, if the ground loop heat exchanger 30 is configured to use a liquid as the refrigeration fluid, then the heat exchanger 42 may be an air-to-liquid or a liquid-to-liquid heat exchanger based on the use of air or liquids in the heat exchanger 42.

The heat extracted by the heat exchanger 42 may then be pumped into the ground through the ground loop heat exchanger 30. The ground loop heat exchanger may transfer the extracted heat into the surrounding Earth. This transfer of heat cools the refrigeration fluid, which may then be pumped back into the heat exchanger 42 and used for further cooling of the power conversion circuitry 12. Indeed, a continuous movement of the refrigeration fluid from the heat exchanger 42 to the ground loop heat exchanger 30 through the pump 40 may be used to absorb heat and transfer the absorbed heat into the ground.

During a winter season, the sensed temperature for the power conversion circuitry 12 may be at a lower range of the rated temperature range. Indeed, the ground temperature may be hotter than the ambient temperature, and so thermal energy from the ground may be used to heat the power conversion circuitry 12. Accordingly, refrigeration fluid heated by the ground through the use of the ground loop heat exchanger 30 may be directed by the pump 40 into the heat exchanger 42. The heat exchanger 42 may then transfer heat into the power conversion circuitry 12, thus improving the operating temperature of the power conversion circuitry 12. After the transfer of ground heat, the now cooler refrigeration fluid (e.g., air) may then be redirected into the ground in order to re-absorb heat. As mentioned above, a continuous movement of the refrigeration fluid from the heat exchanger 42 to the ground loop heat exchanger 30 through the pump 40 may be used to absorb heat from the ground and to transfer the absorbed heat into the power conversion circuitry 12 in a looped fashion.

In certain embodiments, the ground loop heat exchanger 30 may be combined with the surface loop heat exchanger 32. The use of two thermal loops 30 and 32 may further lower the energy used to thermally condition the power conversion circuitry 12. For example, the surface loop heat exchanger 32 may be a smaller system that uses low power. The surface loop heat exchanger 32 may include, for example, fans, surface heat exchangers (e.g., fins, tubes, shells, flat plates), and so forth, suitable for the low power cooling (or heating) of the power conversion circuitry 12. Accordingly, the surface loop heat exchanger 32 may be turned on when the temperature difference between the optimal rated temperature range and actual temperature of the power conversion circuitry 12 is not too great. For example, if the temperature difference between the optimal rated temperature and actual temperature of the power conversion circuitry 12 is of less than 10° C., 5° C., or 2° C., then the surface loop heat exchanger 32 may be turned on.

If the actual temperature of the power conversion circuitry 12 is too different from the optimal rated temperature, then the surface loop heat exchanger 32 may be turned off and the ground loop heat exchanger 30 may be used. However, in certain circumstances, both the surface loop heat exchanger 32 and the ground loop heat exchanger 30 may be used. For example, extra cooling (or heating) may be employed by using both loop heat exchangers 30 and 32 when the ambient temperatures reach very high (or very low) temperatures, such as during very high heat waves or during very cold conditions. Indeed, the use of the surface loop heat exchanger 32 increases the flexibility of the geothermal conditioning system 14 by allowing for multiple modes of operation, such as when using only the surface loop heat exchanger 32, when using only the ground loop heat exchanger 30, and when using both the surface loop heat exchanger 32 and the ground loop heat exchanger 30.

FIG. 3 depicts a liquid-cooled embodiment of the power conversion circuitry 12 incorporating the use of the ground loop heat exchanger 30. The use of a liquid coolant as the refrigeration fluid instead of, for example, air, may lead to higher thermal exchange efficiencies because of an increase in thermal conductivity and specific heat capacity of a liquid refrigeration fluid when compared to a gaseous refrigeration fluid. Thermal conductivity is a physical property that describes how well a substance transfers heat. A liquid typically has a higher thermal conductivity than a gas. For example, water has a thermal conductivity about 25 times higher than the thermal conductivity of air. The specific heat capacity refers to the amount of thermal energy it takes to heat a substance by one degree Celsius. The specific heat capacity of a liquid, such as water, is approximately four times the specific heat capacity of air. Accordingly, in certain embodiments, the liquid refrigeration fluid may include water, alcohol, and/or a glycol. For example, a combination of approximately 50% water and 50% glycol may be used. Such a combination includes anti-freeze properties that enable the thermal fluid to operate during very cold conditions. It is to be understood that other liquid refrigeration fluids may be used that include anti-freeze properties.

In the depicted embodiment, a liquid pump 48 may be used to move the thermal fluid through the ground loop heat exchanger 30. As mentioned above, the movement of the refrigeration fluid may transfer heat into the ground, for example, during the summer, so as to cool the power conversion circuitry 12. Likewise, during winter, the movement of the thermal fluid may transfer heat from the ground into the power conversion circuitry 12, thus heating the power conversion circuitry 12. In certain embodiments, a liquid pump 50 and conduits 52 may be used to further improve thermal conditioning. In these embodiments, the ground loop heat exchanger 30 may first deliver the refrigeration fluid into a heat exchanger 54. The liquid pump 50 may then be actuated by the controller 34 so as to move a second refrigeration fluid through the conduits 52 and the heat exchanger 54 only. Indeed, in one embodiment, the heat exchanger 54, such as a liquid-to-liquid heat exchanger 54, may include multiple chambers such that one set of chambers allows the flow of the refrigeration fluid coming from the ground through the ground loop heat exchanger 30, while a second set of chambers allows the flow of the second refrigeration fluid coming from the liquid pump 50 through the conduits 52.

By selectively turning on the pump 48 in order to move the refrigeration fluid into the heat exchanger 54, and then switching over to the use of the pump 50, much improved energy efficiencies can be realized. In these embodiments, the pump 50 may be a smaller pump 50 requiring less energy to move a liquid than the pump 48. Accordingly, the controller 34 may optimize the thermal conditioning of the power conversion circuitry 12 by using the pump 48 more sparingly. For example, the controller 34 may use the sensor 38 to sense the temperature of the power conversion circuitry 12. If the temperature of the power conversion circuitry 12 exceeds a certain value, then the controller 34 may turn on the pump 50 so as to cool the power conversion circuitry 12. However, the thermal fluid may eventually warm up. Accordingly, the controller 34 may turn off the pump 50 and turn on the pump 48 so as to bring a cooler thermal fluid into the heat exchanger 54. The pump 48 may be turned off and the pump 50 may be turned back on. Indeed, by selectively using the pumps 48 and 50, it may be possible to improve upon the energy required to maintain the power conversion circuitry 12 at a desired temperature range.

In certain embodiments, the pump 48 and the pump 50 are not turned off at the same time. That is, the pump 50 may always be on so as to circulate the refrigeration fluid through the power converter. In these embodiments, the fan 36, the pump 48, or both the fan 36 and the pump 48 may be used to cool the refrigeration fluid circulated by the pump 50. Accordingly, an enhanced cooling may be achieved by continuously pumping refrigeration fluid through pump 50.

Additionally, certain embodiments may combine the use of the ground loop heat exchanger 30 with the surface loop heat exchanger 32. As mentioned above, the use of two thermal loops 30 and 32 may further lower the energy used to thermally condition the power conversion circuitry 12. The surface loop heat exchanger 32 may be a smaller system that uses low power. Accordingly, the surface loop heat exchanger 32 may be turned on when the temperature difference between the optimal rated temperature and the actual temperature of the power conversion circuitry 12 is not too great. For example, if the temperature difference between the optimal rated temperature and actual temperature of the power conversion circuitry 12 is of less than 10° C., 5° C., or 2° C., then the surface loop heat exchanger 32 may be turned on. If the actual temperature of the power conversion circuitry 12 is too different from the optimal rated temperature, then the surface loop heat exchanger 32 may be turned off and the ground loop heat exchanger 30 may be used, or both the surface loop heat exchanger 32 and the ground loop heat exchanger 30 may be used. Such flexibility of thermal conditioning allows for selecting a thermal conditioning mode that may improve energy efficiency of the geothermal conditioning system 14.

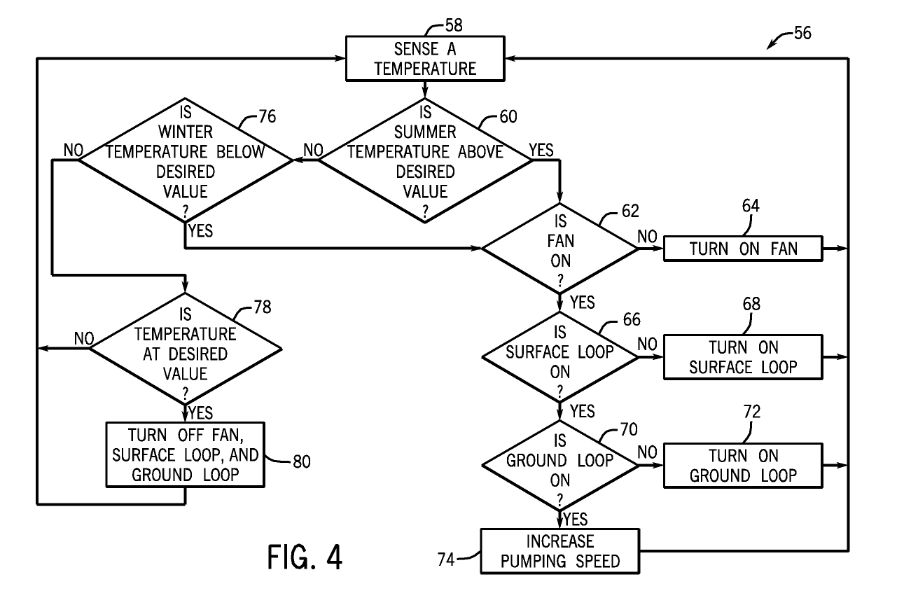

FIG. 4 is a flow chart of exemplary logic 56 that may be used, for example, by the controller 34 to direct the cooling or heating of the power conversion circuitry 12. The logic 56 may include non-transitory machine readable code or computer instructions that may be used by a computing device (e.g., closed-loop controller) to transform sensor inputs, such as temperature inputs, into outputs such as actuator outputs. The logic 56 may first sense a temperature of the power conversion circuitry 12 (block 58), for example, by using the sensor 38. If the summer temperature of the power conversion circuitry 12 is above a desired value (decision 58), then the logic may determine if a fan, such as the fan 36, is on (decision 62). If the fan is not on, then the logic 56 may turn the fan on (block 64). Turning the on the fan may be sufficient to cool the power conversion circuitry 12, so the logic 58 may again sense the temperature (block 58).

If the fan is on (decision 62), then extra cooling may be desired. Accordingly, the logic 56 may determine if the surface loop heat exchanger 32 is on (decision 66). If the surface loop heat exchanger 32 is not on, then the logic 64 may turn on the surface loop heat exchanger 32. Turning on the surface loop heat exchanger 32 may add sufficient cooling of the power conversion circuitry 12. Accordingly, the logic 56 may again sense the temperature (block 58). If the surface loop heat exchanger 32 is already on (decision 66), then the logic 56 may determine if the ground loop heat exchanger 30 is turned on (decision 70). If the ground loop heat exchanger 30 is not turned on, then additional cooling may be achieved by turning on the ground loop heat exchanger 30 (block 72). Once the ground loop heat exchanger 30 has been turned on (block 72), the logic 56 may again sense the temperature (block 58). If the ground loop heat exchanger 30 is already on, then the logic 56 may direct an increase in pumping speed of, for example, the pump 40 or 48 (block 74). Increasing the pumping speed may increase the cooling of the power conversion circuitry 12 by pumping more thermal energy into the ground.

The logic 58 may use a similar process for heating the power conversion circuitry 12, for example, during winter. More specifically, if the temperature of the power conversion circuitry 12 during winter is below a desired temperature (decision 76), then a check is made to determine if the fan is on (decision 62). If the fan is not on, the fan may be turned on (block 64) in order to blow hot air onto the power conversion circuitry 12. This convection heating may be sufficient to warm the power conversion circuitry 12 to desired temperatures. Accordingly, the logic 56 may again sense the temperature (block 58). If the fan is already turned on, then a check may be made to determine if the surface loop heat exchanger 32 is on (decision 66). If the surface loop heat exchanger 32 is not on, then the surface loop heat exchanger 32 may be turned on (block 68). Turning on the surface loop heat exchanger 32 may direct heat into the power conversion circuitry 12 and may result in reaching a desired temperature. The temperature may then be sensed again (block 58).

If the surface loop heat exchanger 32 is determined to be on (decision 66), then a check may be made to determine if the ground loop heat exchanger 30 is turned on (decision 70). If the ground loop heat exchanger 30 is not turned on, then the ground loop heat exchanger 30 may be turned on, for example, by actuating the pump 40 or 48 (block 72). The ground loop heat exchanger 30 may thus be used to extract heat from the ground and direct the extracted heat onto the power conversion circuitry 12. The logic 56 may then sense the temperature (block 58). If the ground loop heat exchanger 30 is determined to be on (decision 70), then the logic 56 may direct an increase in pumping speed (block 74). Increasing the pumping speed may extract more heat from the ground, thus adding extra heat to the power conversion circuitry 12.

If the logic 56 determines that the temperature of the power conversion circuitry 12 is approximately at a desired value (decision 78), then the fan 36, the surface loop heat exchanger 32, and the ground loop heat exchanger 30 may be turned off (block 80). Turning off the thermal conditioning of the power conversion circuitry 12 when the sensed temperature is at approximately a desired value may increase energy efficiency by avoiding the use of unnecessary thermal conditioning. Indeed, the techniques disclosed herein allow for an improved energy use for the thermal conditioning of the power conversion circuitry 12. Additionally, the techniques disclosed herein allow for simpler and more easily maintainable thermal conditioning equipment, thus increasing operational life and reducing overall system costs.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A thermally conditioned power conversion system comprising:
power conversion circuitry;
a ground loop heat exchanger; and
a controller configured to control cooling or heating of the power conversion circuitry via a refrigeration fluid circulated through the ground loop heat exchanger.

2. The system of claim 1, comprising a surface loop heat exchanger, wherein the controller controls the cooling or heating of the power conversion circuitry by combining the use of both the surface loop heat exchanger and the ground loop heat exchanger.

3. The system of claim 2, wherein the surface loop heat exchanger comprises a fan, a folded fin, a plurality of tubes, or a combination thereof.

4. The system of claim 1, wherein the ground loop heat exchanger comprises a conduit buried underground, a conduit disposed underwater, or a combination thereof.

5. The system of claim 1, comprising a fan, wherein the controller controls air displaced by the fan to cool or heat the power conversion circuitry.

6. The system of claim 3, wherein the refrigeration fluid comprises a gas.

7. The system of claim 3, wherein the refrigeration fluid comprises a liquid.

8. The system of claim 7, wherein the liquid comprises water, alcohol, glycol, or a combination thereof.

9. The system of claim 1, wherein the power conversion circuitry comprises a motor drive.

10. The system of claim 1, wherein the power conversion circuitry comprises a solar inverter.

11. A thermally conditioned power conversion system comprising:
power conversion circuitry configured to receive power from a power system and to convert the power received from the power system into an alternating current (AC) power or a direct current (DC) power;
a pump configured to pump a refrigeration fluid; and
a ground loop heat exchanger configured to cool or heat the power conversion circuitry by circulation of the refrigeration fluid pumped by the pump.

12. The system of claim 11, wherein the power system comprises a solar panel, a wind turbine, a solar concentrator, or a combination thereof.

13. The system of claim 11, comprising a surface loop heat exchanger configured to cool or heat the power conversion circuitry.

14. The system of claim 11, wherein the ground loop heat exchanger comprises a conduit buried underground, a conduit disposed underwater, or a combination thereof.

15. The system of claim 11, wherein the refrigeration fluid comprises a liquid.

16. A non-transitory computer-readable medium comprising code adapted to:
receive a value representative of a temperature of power conversion circuitry;
calculate a difference between the received value representative of the temperature of the power conversion circuitry and a desired temperature; and
output a command signal to pump a refrigeration fluid through a ground loop heat exchanger based upon the calculated difference to cool or heat the power conversion circuitry.

17. The non-transitory computer-readable medium of claim 16, comprising code adapted to actuate a surface loop heat exchanger based upon the calculated difference.

18. The non-transitory computer-readable medium of claim 17, comprising code adapted to actuate a fan based upon the calculated difference.

19. The non-transitory computer-readable medium of claim 18, comprising pumping the refrigeration fluid through the ground loop heat exchanger only if the calculated difference indicates that the power conversion circuitry is in need of heating or cooling.

20. The non-transitory computer-readable medium of claim 18, comprising actuating the fan only if the calculated difference indicates that the power conversion circuitry is in need of heating or cooling.
